(19) United States
(12) Patent Application Publication
(10) Pub. No.: US 2014/0332074 A1
(43) Pub. Date: Nov. 13, 2014

(54) SOLAR CELL MODULE

(71) Applicant: Win Win Precision Technology Co., Ltd., Hsinchu County (TW)

(72) Inventors: Cheng-Lien Wang, Taoyuan County (TW); Chien-Chun Hsieh, Hualien County (TW)

(73) Assignee: Win Win Precision Technology Co., Ltd., Hsinchu County (TW)

(21) Appl. No.: 14/217,499

(22) Filed: Mar. 18, 2014

(30) Foreign Application Priority Data
May 13, 2013 (TW) 102208875

(51) Int. Cl. H01L 31/052

(52) U.S. Cl. CPC H01L 31/052
USPC 136/259

(57) ABSTRACT

A solar cell module is provided, wherein the solar cell module includes a solar cell device, a first protective film, a second protective film, a cover plate, a backsheet and a plurality of thermal radiation particles. The solar cell device includes a first surface and a second surface opposite to the first surface. The first protective film is located on the first surface, and the second protective film is located on the second surface. The cover plate is located on the first protective film, and the first protective film is located between the solar cell device and the cover plate. The backsheet is located on the second protective film, and the second protective film is located between the solar cell device and the backsheet, and the thermal radiation particles are distributed in the backsheet.

### CROSS-REFERENCE TO RELATED APPLICATION

This application claims the priority benefit of Taiwan application serial no. 102208875, filed on May 13, 2013. The entirety of the above-mentioned patent application is hereby incorporated by reference herein and made a part of this specification.

### BACKGROUND

1. Technical Field

The invention relates to a solar cell module.

2. Related Art

Under the circumstances of petrochemical energy shortage and growing demand for energy, development of renewable energy has become one of today's very important projects. The renewable energy generally refers to sustainable and non-polluting natural energy, such as solar energy, wind energy, water energy, tidal energy or biomass energy, etc., in which utilization of the solar energy becomes very important and popular in research of energy development in recent years.

A solar cell is a photovoltaic device for energy conversion, which is capable of converting light energy into electric energy when the solar cell is irradiated by sunlight. The solar cells include monocrystalline silicon solar cells, polycrystalline silicon solar cells, amorphous silicon solar cells, thin-film solar cells and dye solar cells. Taking a silicon-based solar cell as an example, a high-purity semiconductor material (silicon) is added with some impurities to present different properties. When the sunlight irradiates the semiconductor material of the solar cell, the energy provided by photons probably excites electrons in the semiconductor material to produce electron-hole pairs. The electron-hole pairs are affected by an built-in potential and move towards opposite directions, where the holes move towards a direction of an electric field, and the electrons move towards the opposite direction. If the solar cell is connected to a load through a wire to form a loop, a current may flow through the load, and this is a power generation principle of the solar cell, which is also referred to as a photovoltaic effect.

A solar cell module may produce thermal energy during a process of photoelectric conversion or when the solar cell module is irradiated by the sunlight for a long time, and if the thermal energy cannot be effectively dissipated, a back thermal problem is encountered, which leads to reduction of the photoelectric conversion efficiency. As the solar cell modules gradually draw people's attention and various manufacturers plunge into the solar cell module market, in order to achieve high product competitiveness, the solar cell module must have a good heat dissipation effect to achieve good photoelectric conversion efficiency.

### SUMMARY

The invention is directed to a solar cell module having a good heat dissipation effect.

The invention provides a solar cell module including a solar cell device, a first protective film, a second protective film, a cover plate, a backsheet and a plurality of thermal radiation particles. The solar cell device includes a first surface and a second surface opposite to the first surface. The first protective film is located on the first surface, and the second protective film is located on the second surface. The cover plate is located on the first protective film, and the first protective film is located between the solar cell device and the cover plate. The backsheet is located on the second protective film, and the second protective film is located between the solar cell device and the backsheet, and the thermal radiation particles are distributed in the backsheet.

In an embodiment of the invention, the backsheet is a stacked layer of multiple layers, and the thermal radiation particles are distributed in at least one layer of the stacked layer.

In an embodiment of the invention, a distribution thickness of the thermal radiation particles is between 10 nanometers and 100 micrometers.

In an embodiment of the invention, the solar cell device includes a first electrode layer, a photoelectric conversion layer, a second electrode layer and a plurality of metal electrodes, where the photoelectric conversion layer has an upper surface and a lower surface opposite to the upper surface. The first electrode layer is located on the upper surface, and the second electrode layer is located on the lower surface. The metal electrodes are located on the lower surface and are electrically connected to the second electrode layer.

In an embodiment of the invention, the photoelectric conversion layer is a stacked structure of a P-type doped layer and an N-type doped layer, or a stacked structure of the P-type doped layer, an intrinsic layer, and the N-type doped layer.

In an embodiment of the invention, the solar cell module further includes a thermal radiation layer located on the second electrode layer, and the thermal radiation layer exposes the metal electrodes.

In an embodiment of the invention, the thermal radiation layer includes a plurality of thermal radiation patterns, and a gap is maintained between each of the thermal radiation patterns and the adjacent metal electrode.

In an embodiment of the invention, the thermal radiation particles are further distributed in the second protective film.

According to the above descriptions, in the solar cell module of the invention, by disposing the thermal radiation particles in the backsheet, the heat generated by the solar cell device can be conducted out of the solar cell module, so as to mitigate the back thermal problem to improve the photoelectric conversion efficiency of the solar cell module.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a solar cell module according to a first embodiment of the invention.

FIG. 2 is a cross-sectional view of a solar cell module according to a second embodiment of the invention.

FIG. 3 is a cross-sectional view of a solar cell module according to a third embodiment of the invention.

FIG. 4 is a cross-sectional view of a solar cell module according to a fourth embodiment of the invention.

### DETAILED DESCRIPTION OF DISCLOSED EMBODIMENTS

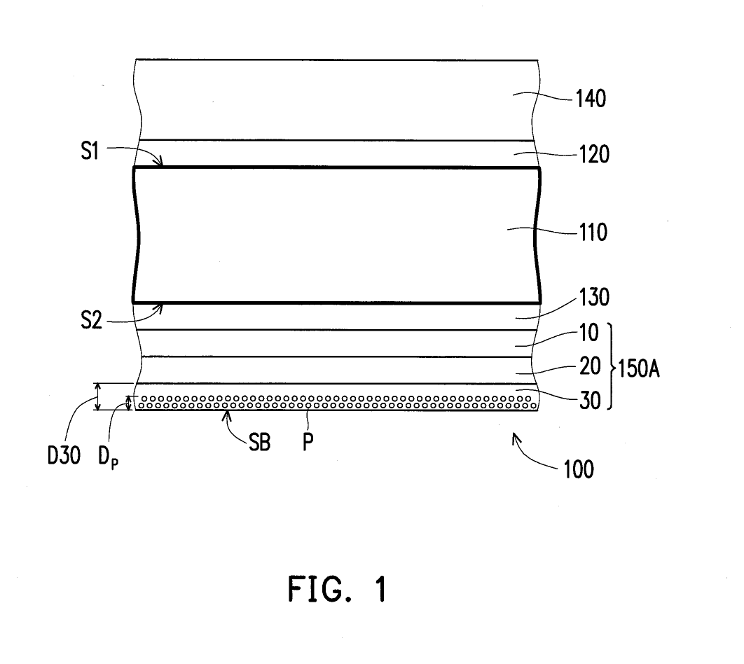

FIG. 1 is a cross-sectional view of a solar cell module according to a first embodiment of the invention. Referring to FIG. 1, the solar cell module 100 of the present embodiment includes a solar cell device 110, a first protective film 120, a second protective film 130, a cover plate 140, a backsheet 150A and a plurality of thermal radiation particles P.

In detail, the solar cell device 110 of the present embodiment can be silicon solar cell, a compound semiconductor solar cell, a dye solar cell or a thin film solar cell, where the silicon solar cell may include a monocrystalline silicon solar cell, a polycrystalline silicon solar cell and an amorphous silicon solar cell. Moreover, the solar cell device 110 includes a first surface S1 and a second surface S2 opposite to the first surface S1. In the present embodiment, the first surface S1 is, for example, a surface of the solar cell device 110 facing the sunlight or ambient light, a so-called light receiving surface, and the second surface S2 is a surface back to the sunlight or the ambient light, i.e. a so-called non-light receiving surface or a shady surface.

The first protective film 120 is located on the first surface S1, and the second protective film 130 is located on the second surface S2. Namely, the solar cell device 110 is located between the first protective film 120 and the second protective film 130. The first protective film 120 and the second protective film 130 are used to package one or a plurality of solar cell devices 110 for decreasing influence of the external environment (for example, vapor, temperature, ultraviolet, etc.) on the solar cell device 110. For example, a material of the first protective film 120 and the second protective film 130 can be ethylene vinyl acetate (EVA), poly vinyl butyral (PVB), polyolefin, polyurethane, silicone or a transparent polymer insulation adhesive material.

The cover plate 140 is located on the first protective film 120, and the first protective film 120 is located between the solar cell device 110 and the cover plate 140. The cover plate 140 is configured to protect the device (for example, the solar cell device 110) located under to cover plate 140, so as to improve reliability of the solar cell module 100. In detail, the cover plate 140 is, for example, a substrate having a high light transmittance and a high structural strength. For example, the cover plate 140 is a glass substrate.

The backsheet 150A is located on the second protective film 130, and the second protective film 130 is located between the solar cell device 110 and the backsheet 150, and the thermal radiation particles P are distributed in the backsheet 150A. The backsheet 150A is, for example, used for decreasing influence of the external environment (for example, vapor, temperature, ultraviolet, etc.) on the solar cell device 110. For example, the backsheet 150A can be a stack layer of multiple layers, and the thermal radiation particles P are distributed in at least one layer of the stacked layer.

In detail, the backsheet 150A of the present embodiment includes a backsheet first layer 10, a backsheet second layer 20, a backsheet third layer 30 where the backsheet second layer 20 is located between the backsheet first layer 10 and the backsheet third layer 30, and the backsheet first layer 10 is located between the backsheet second layer 20 and the second protective film 130. Namely, the backsheet first layer 10 of the backsheet 150A is disposed at a side close to the second protective film 130, and the backsheet third layer 30 is disposed at a side away from the second protective film 130.

The backsheet first layer 10, the backsheet second layer 20 and the backsheet third layer 30 are, for example, respectively a polymer layer with a good insulation property, water resistance property and aging resistance property. A common three-layer stacked structure is, for example, formed by three layers of polyvinylidene difluoride (PVDF)/polyethylene terephthalate (PET)/PVDF, where the backsheet first layer 10 and the backsheet third layer 30 (PVDF), for example, have a good anti-environmental erosion capability, the backsheet second layer 20, for example, has a good insulation capability, and the backsheet first layer 10, the backsheet second layer 20 and the backsheet third layer 30 are, for example, adhered pairwise through adhesion layers. However, the number of film layers of the backsheet 150A, the stacking manner of the film layers or the material of each film layer are not limited by the invention. In other embodiments, the material of the aforementioned film layer (the backsheet first layer 10, the backsheet second layer 20 and the backsheet third layer 30) can also be one of polymer materials of polycarbonate (PC), polyvinylidene chloride (PVDC), polyethylene terephthalate glycol (PETG), polyethylene naphthalate (PEN), polyvinyl fluoride (PVF), or a stacked layer of a combination thereof.

Since a thermal radiation amount and temperature are positively correlated, if the thermal radiation particles P are distributed adjacent to a surface of the backsheet 150A contacts the air, a more significant heat dissipation effect is achieved. In the present embodiment, the thermal radiation particles P are, for example, formed in the backsheet third layer 30 at a side contacting the air through doping, i.e. the thermal radiation particles P are distributed adjacent to a bottom surface SB of the backsheet 150A. In this way, the thermal radiation particles P can conduct the heat of the solar cell device 110 out of the solar cell module 100 through thermal radiation, so as to mitigate the back thermal problem to improve the photoelectric conversion efficiency of the solar cell module 100. It should be noticed that the number of film layers or position where the thermal radiation particles P are distributed is not limited by the invention. In other embodiments, the thermal radiation particles P can also be doped in the backsheet first layer 10 or the backsheet second layer 20, alternatively, the thermal radiation particles P can also be doped in at least two of the backsheet first layer 10, the backsheet second layer 20 and the backsheet third layer 30 to achieve the heat dissipation effect.

The thermal radiation particles P of the present embodiment are, for example, silicon carbide (SiC) particles, and a distribution thickness Dp of the thermal radiation particles P is smaller than or equal to a thickness D30 of the backsheet third layer 30. The distribution thickness Dp refers to the shortest distance between the thermal radiation particles P located at an uppermost layer and the thermal radiation particles P located at a lowermost layer in the distribution region of the thermal radiation particles P. In the present embodiment, the distribution thickness Dp of the thermal radiation particles P is, for example, between 10 nanometers and 100 micrometers.

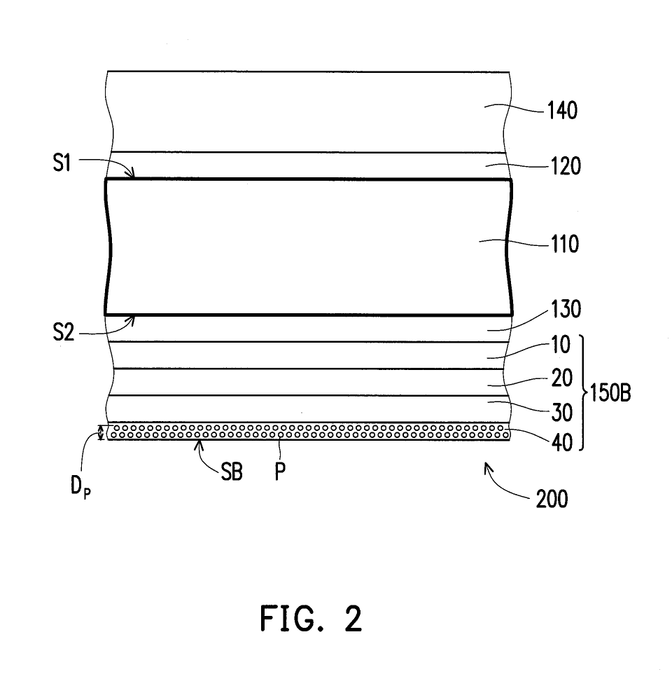

FIG. 2 is a cross-sectional view of a solar cell module according to a second embodiment of the invention. Referring to FIG. 2, the solar cell module 200 of the present embodiment has a similar structure and film layers with that of the solar cell module 100 of FIG. 1, and a difference there between is that a backsheet 150B of the solar cell module 200 of the present embodiment further includes a backsheet fourth layer 40 besides the aforementioned backsheet first layer 10, backsheet second layer 20 and backsheet third layer 30, where the thermal radiation particles P are distributed in the backsheet fourth layer 40, and the backsheet third layer 30 of the present embodiment is located between the backsheet second layer 20 and the backsheet fourth layer 40. Namely, the backsheet fourth layer 40 of the present embodiment is located at the bottom surface of the solar cell module 200.

In detail, in the present embodiment, the thermal radiation particles P of the present embodiment can be doped in a polymer substrate (for example, the backsheet fourth layer 40 made of resin), and then the backsheet fourth layer 40 is formed on a bottom surface SB of the backsheet 150B through coating or adhesion. In this way, the thermal radiation particles P can conduct the heat of the solar cell device 110 out of the solar cell module 200 through thermal radiation, so as to mitigate the back thermal problem to improve the photoelectric conversion efficiency of the solar cell module 200. It should be noticed that the configuration position of the backsheet fourth layer 40 distributed with the thermal radiation particles P or the number of the backsheet fourth layers 40 are not limited by the invention. In other embodiments, the backsheet fourth layer 40 can also be disposed between the backsheet second layer 20 and the backsheet third layer 30 or disposed between the backsheet first layer 10 and the backsheet second layer 20, or disposed between each two of the backsheet first layer 10, the backsheet second layer 20 and the backsheet third layer 30 to achieve the heat dissipation effect. Moreover, the distribution thickness Dp of the thermal radiation particles P of the present embodiment is, for example, between 10 nanometers and 100 micrometers.

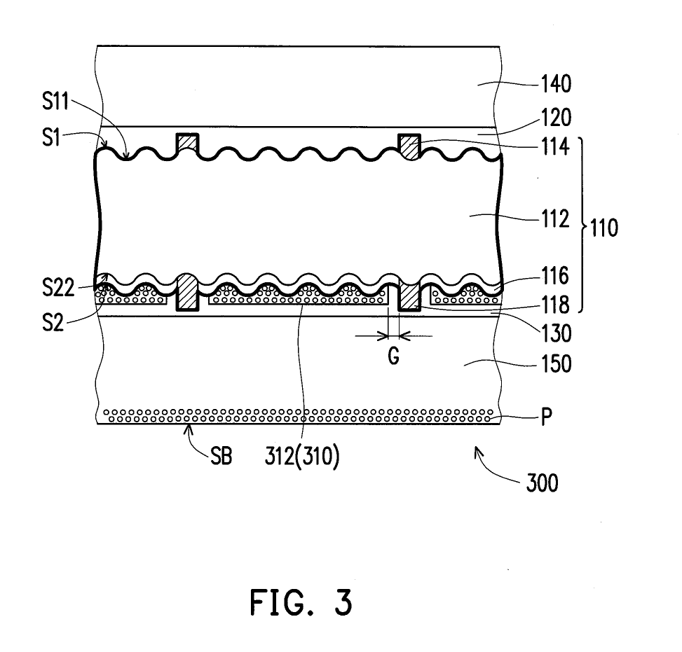

FIG. 3 is a cross-sectional view of a solar cell module according to a third embodiment of the invention. Referring to FIG. 3, the solar cell module 300 of the present embodiment has a similar structure and film layers with that of the solar cell module 100 of FIG. 1 and the solar cell module 200 of FIG. 2, where a backsheet 150 of the present embodiment may adopt the structure of the backsheet 150A of FIG. 1A or the structure of the backsheet 150B of FIG. 2. Namely, in the backsheet 150 of the present embodiment, the thermal radiation particles P can be distributed in the backsheet 150 through doping, coating or adhesion. Moreover, a main difference between the solar cell module 300 and the solar cell modules 100 and 200 is that the solar cell module 300 of the present embodiment further includes a thermal radiation layer 310, where the thermal radiation layer 310 is located on a part region of the second surface S2 of the solar cell device 110.

In detail, the solar cell device 110 of the present embodiment, for example, includes a photoelectric conversion layer 112, a first electrode layer 114, a second electrode layer 116 and a plurality of metal electrodes 118. The photoelectric conversion layer 112 has an upper surface S11 and a lower surface S22 opposite to the upper surface S11. The first electrode layer 114 is located on the upper surface S11, and the second electrode layer 116 is located on the lower surface S22. Moreover, the metal electrodes 118 are located on the lower surface S22 and are electrically connected to the second electrode layer 116.

The photoelectric conversion layer 112 can be a stacked structure of a P-type doped layer and an N-type doped layer, or a stacked structure of the P-type doped layer, an intrinsic layer, and the N-type doped layer. Moreover, the upper surface S11 and the lower surface S22 of the photoelectric conversion layer 112 can be a textured surface (i.e. a serrated surface shown in FIG. 3) to enhance absorption of sunlight, though the upper surface S11 and the lower surface S22 of the photoelectric conversion layer 112 are not limited to be the textured surface.

Since the first electrode layer 114 is disposed on the upper surface S11 of the photoelectric conversion layer 112 (i.e. a light receiving surface of the photoelectric conversion layer 112), and the first electrode layer 114 is generally made of a metal material with good conductivity, in order to decrease a proportion that the first electrode layer 114 of the metal material shields the incident light, the first electrode layer 114 can be designed into a structure having a special pattern. In detail, the first electrode layer 114 may include busbars traversing the photoelectric conversion layer 112 and a plurality of fine finger electrodes stretching out from the busbars, where the busbars may respectively extend along a first direction and are arranged along a second direction, and the finger electrodes respectively extend along the second direction and are arranged along the first direction. Generally, the busbars and the finger electrodes are disposed vertically, namely, the first direction is perpendicular to the second direction, though the invention does not limit the included angle of the first direction and the second direction and the pattern of the first electrode layer 114. In other embodiments, the pattern of the first electrode layer 114 can also be a lattice pattern, a striped pattern or other patterns suitable for collecting carriers. Alternatively, the solar cell device 110 can be a back contact solar cell device, and through dorsalization of the busbars, the proportion that the first electrode layer 114 on the light receiving surface shields the incident light is decreased.

The second electrode layer 116 is, for example, a so-called back surface field (BSF) metal layer, which is used for increasing collection of the carriers and retrieving the unabsorbed photons. Moreover, the metal electrodes 118 are, for example, used for converging the current collected by the second electrode layer 116.

The thermal radiation layer 310 is located on the second electrode layer 116, and the thermal radiation layer 310 exposes the metal electrodes 118. In the present embodiment, the thermal radiation layer 310 includes a plurality of thermal radiation particles, and the thermal radiation particles are, for example, silicon carbide particles.

Further, the thermal radiation layer 310 of the present embodiment includes a plurality of thermal radiation patterns 312, and a gap G is maintained between each of the thermal radiation patterns 312 and the adjacent metal electrode 118. In this way, when a subsequent welding process is performed to connect a plurality of the solar cell devices 110 in series, a problem of fragmentation is reduced and a yield of the solar cell module 300 is thereby improved.

In the present embodiment, the thermal radiation pattern 312 is, for example, formed through screen printing. By configuring the gap G, a margin for aligning a stencil (not shown) used for fabricating the thermal radiation layer 310 and the metal electrodes 118 is provided. In this way, if there is a slight deviation in alignment, the yield of the solar cell module 300 is not influenced. Moreover, since the pattern of the thermal radiation layer 310 can be adjusted through a pattern reserved on the stencil, when the pattern of the metal electrodes 118 is changed, by changing the pattern reserved on the stencil, the thermal radiation pattern 312 is adjusted. Namely, the thermal radiation layer 310 of the solar cell module 300 of the present embodiment has a high margin in pattern adjustment.

In the present embodiment, a distribution plane of the thermal radiation particles P in the backsheet 150 is, for example, parallel to the thermal radiation layer 310. Therefore, the solar cell module 300 of the present embodiment can effectively conduct the heat of the solar cell device 110 out of the solar cell module 300 through a thermal coupling effect between the thermal radiation layer 310 and the thermal radiation particles P distributed in the backsheet 150, so as to mitigate the back thermal problem to effectively dissipate the heat of the solar cell device 110 and effectively enhance the photoelectric conversion efficiency of the solar cell module 300.

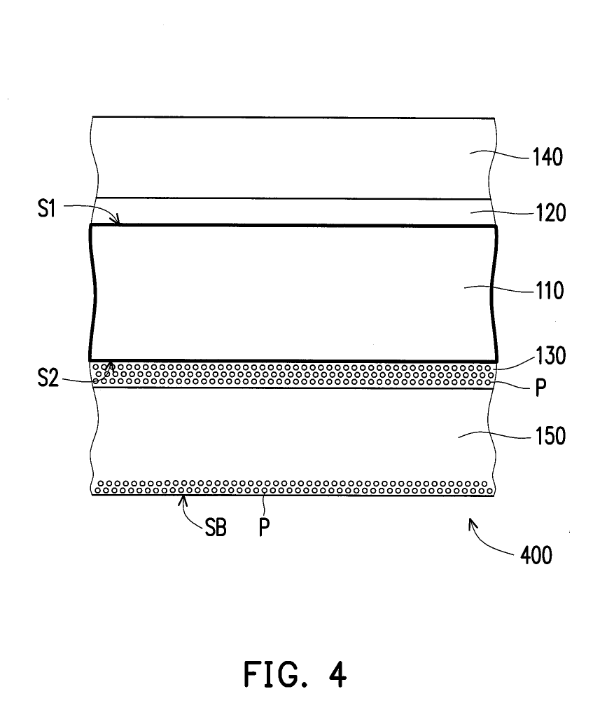

FIG. 4 is a cross-sectional view of a solar cell module according to a fourth embodiment of the invention. Referring to FIG. 4, the solar cell module 400 of the present embodiment has a similar structure and film layers with that of the solar cell module 100 of FIG. 1 and the solar cell module 200 of FIG. 2, where the backsheet 150 of the present embodiment may adopt the structure of the backsheet 150A of FIG. 1A or the structure of the backsheet 150B of FIG. 2. Moreover, a main difference between the solar cell module 400 and the solar cell modules 100 and 200 is that the thermal radiation particles P of the solar cell module 400 of the present embodiment are further distributed in the second protective film 130.

In the present embodiment, the thermal radiation particles P are, for example, evenly distributed in the second protective film 130. Moreover, distribution planes of the thermal radiation particles P distributed in the backsheet 150 and the second protective film 130 are, for example, parallel to each other. Therefore, the solar cell module 400 of the present embodiment can effectively conduct the heat of the solar cell device 110 out of the solar cell module 400 through a thermal coupling effect of the thermal radiation particles P distributed in the second protective film 130 and the backsheet 150, so as to mitigate the back thermal problem to effectively dissipate the heat of the solar cell device 110 and effectively enhance the photoelectric conversion efficiency of the solar cell module 400.

In summary, in the solar cell module of the invention, by disposing the thermal radiation particles in the backsheet, the heat generated by the solar cell device can be conducted out of the solar cell module, so as to mitigate the back thermal problem to improve the photoelectric conversion efficiency of the solar cell module. Moreover, the thermal radiation particles in the backsheet can improve the fire endurance capability of the backsheet. Therefore, when a fire accident occurs, the thermal radiation particles in the backsheet can decrease the speed at which the backsheet is burned and thus deformed. Furthermore, since the backsheet has good thermal radiation absorption characteristics, when the solar cell device is covered by snow, thermal radiation particles in the backsheet are prone to absorb the thermal radiation from the external environment or the roof where the solar cell device is disposed, and thereby the melting process of accumulated snow on the solar cell device can be speeded up and thus speed up the process of generating electricity.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A solar cell module, comprising:
a solar cell device, having a first surface and a second surface opposite to the first surface;
a first protective film, located on the first surface;
a second protective film, located on the second surface;
a cover plate, located on the first protective film, wherein the first protective film is located between the solar cell device and the cover plate;
a backsheet, located on the second protective film, wherein the second protective film is located between the solar cell device and the backsheet; and
a plurality of thermal radiation particles, distributed in the backsheet.

2. The solar cell module as claimed in claim 1, wherein the backsheet is a stacked layer of multiple layers, and the thermal radiation particles are distributed in at least one layer of the stacked layer.

3. The solar cell module as claimed in claim 1, wherein a distribution thickness of the thermal radiation particles is between 10 nanometers and 100 micrometers.

4. The solar cell module as claimed in claim 1, wherein the solar cell device comprises a first electrode layer, a photoelectric conversion layer, a second electrode layer and a plurality of metal electrodes, wherein the photoelectric conversion layer has an upper surface and a lower surface opposite to the upper surface, the first electrode layer is located on the upper surface, and the second electrode layer is located on the lower surface, and the metal electrodes are located on the lower surface and are electrically connected to the second electrode layer.

5. The solar cell module as claimed in claim 4, wherein the photoelectric conversion layer is a stacked structure of a P-type doped layer and an N-type doped layer, or a stacked structure of the P-type doped layer, an intrinsic layer, and the N-type doped layer.

6. The solar cell module as claimed in claim 4, further comprises a thermal radiation layer, wherein the thermal radiation layer is located on the second electrode layer, and the thermal radiation layer exposes the metal electrodes.

7. The solar cell module as claimed in claim 6, wherein the thermal radiation layer comprises a plurality of thermal radiation patterns, and a gap is respectively maintained between each of the thermal radiation patterns and the adjacent metal electrodes.

8. The solar cell module as claimed in claim 1, wherein the thermal radiation particles are further distributed in the second protective film.
